(19) United States
(12) Patent Application Publication
(10) Pub. No.: US 2024/0242983 A1
(43) Pub. Date: Jul. 18, 2024

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Motonari TAKEBAYASHI, Toyama (JP); Kazuya NABETA, Toyama (JP); Atsuya SAKANO, Toyama (JP); Katsuhiko YAMAMOTO, Toyama (JP)

(21) Appl. No.: 18/541,921

(22) Filed: Dec. 15, 2023

(30) Foreign Application Priority Data
Jan. 13, 2023 (JP) 2023-003436

(51) Int. Cl. H01L 21/67

(52) U.S. Cl. CPC H01L 21/67115; H01L 21/67196; H01L 21/67248; H01L 21/67276

(57) ABSTRACT

There is provided a technique capable of improving the uniformity of heating the substrate in the heat treatment process using the electromagnetic wave. The technique includes a process chamber in which a substrate is processed; an electromagnetic wave source configured to output a first electromagnetic wave and a second electromagnetic wave at least partially at the same time to the process chamber; and a frequency controller configured to be capable of controlling at least one of a frequency of the first electromagnetic wave or a frequency of the second electromagnetic wave.

### CROSS REFERENCE TO RELATED APPLICATIONS

This non-provisional U.S. patent application is based on and claims priority under 35 U.S.C. § 119 of Japanese Patent Application No. 2023-003436, filed on Jan. 13, 2023, in the Japanese Patent Office, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

As a part of a manufacturing process of a semiconductor device by processing a substrate such as a semiconductor substrate, a heat treatment process (annealing process) using an electromagnetic wave may be performed.

However, in the heat treatment process using the electromagnetic wave, when the substrate is heated non-uniformly, the substrate may warp or crack.

### SUMMARY

According to the present disclosure, there is provided a technique capable of improving a uniformity of heating a substrate in a heat treatment process using an electromagnetic wave.

According to an aspect of the present disclosure, there is provided a technique that includes: a process chamber in which a substrate is processed; an electromagnetic wave source configured to output a first electromagnetic wave and a second electromagnetic wave at least partially at the same time to the process chamber; and a frequency controller configured to be capable of controlling at least one of a frequency of the first electromagnetic wave or a frequency of the second electromagnetic wave.

### BRIEF DESCRIPTION OF THE DRAWINGS

FIG. 1 is a diagram schematically illustrating a vertical cross-section of a substrate processing apparatus preferably used in one or more embodiments of the present disclosure.

FIG. 2 is a diagram schematically illustrating a vertical cross-section of a single wafer type process furnace of the substrate processing apparatus preferably used in the embodiments of the present disclosure.

FIG. 3 is a diagram schematically illustrating a control system of an electromagnetic wave supplier of the substrate processing apparatus preferably used in the embodiments of the present disclosure.

FIG. 4 is a diagram schematically illustrating a shrinkage amount distribution of an amorphous silicon film processed by changing frequencies of MW1 and MW2 by a frequency control.

FIG. 5 is a diagram schematically illustrating the shrinkage amount distribution of the amorphous silicon film processed under a sixth condition after being processed under a third condition shown in FIG. 4.

FIG. 6 is a diagram schematically illustrating a shrinkage amount distribution of a silicon oxycarbide film processed by changing a phase difference between the MW1 and the MW2 by a phase control.

FIG. 7 is a block diagram schematically illustrating a configuration of a controller and related components of the substrate processing apparatus preferably used in the embodiments of the present disclosure.

FIG. 8A is a flow chart schematically illustrating an exemplary flow of a substrate processing according to the embodiments of the present disclosure.

FIG. 8B is a flow chart schematically illustrating another exemplary flow of the substrate processing according to the embodiments of the present disclosure.

### DETAILED DESCRIPTION

### Embodiments of Present Disclosure

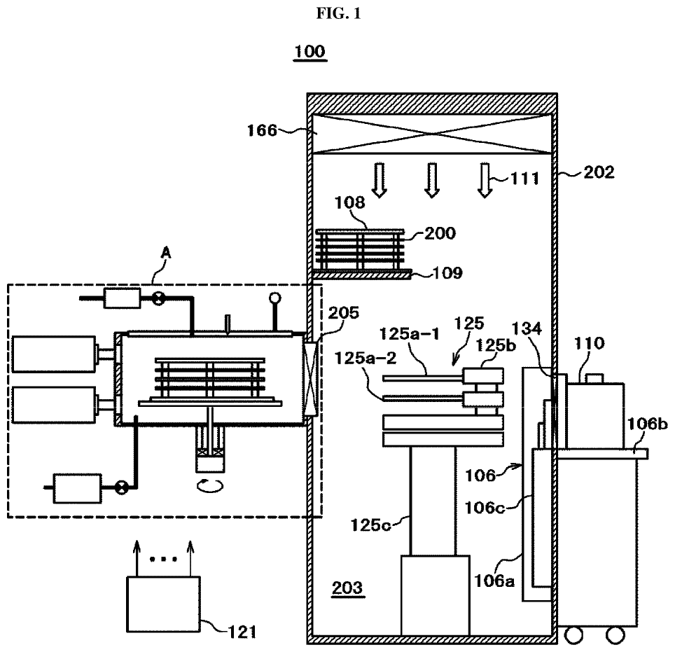

Hereinafter, one or more embodiments (also simply referred to as “embodiments”) of the technique of the present disclosure will be described in detail with reference to FIGS. 1 through 7 and FIGS. 8A and 8B. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

The present embodiments of the present disclosure will be described by way of an example in which a substrate processing apparatus 100 is configured as a single wafer type heat treatment apparatus capable of performing various kinds of heat treatments (also referred to as “heat treatment processes”) on a wafer 200 or a plurality of wafers including the wafer 200. The plurality of wafers including the wafer 200 may also be simply referred to as “wafers 200”. For example, in the present embodiments, the substrate processing apparatus 100 is configured as an apparatus capable of performing an annealing process (modification process) by using an electromagnetic wave described later. In the substrate processing apparatus 100, a FOUP (Front Opening Unified Pod, hereinafter, also referred to as a “pod”) 110 is used as a storage container (also referred to as a “carrier”) in which the wafer 200 serving as a substrate is accommodated. The pod 110 is also used as a transfer container when the wafer 200 is transferred between various substrate processing apparatuses including the substrate processing apparatus 100.

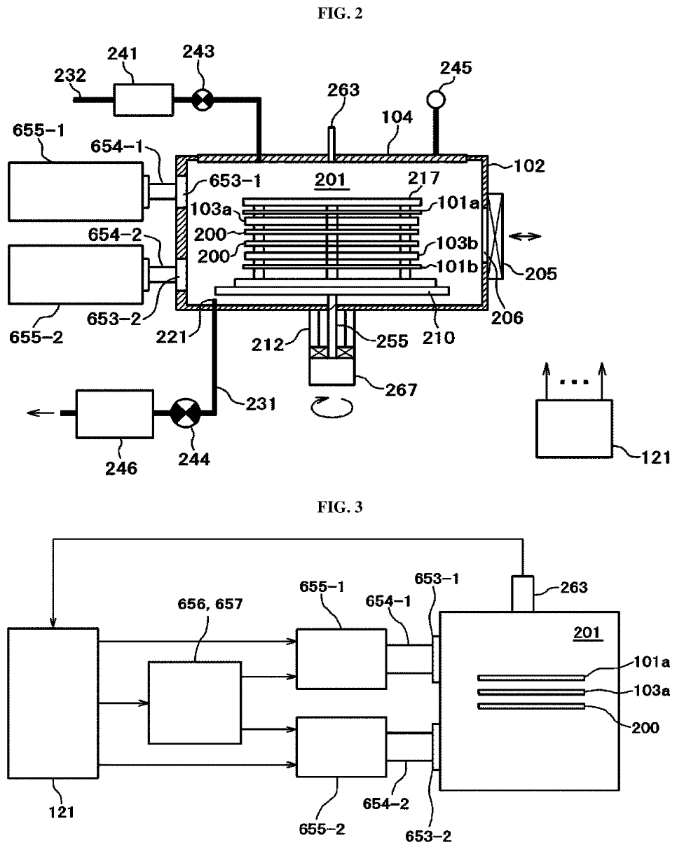

As shown in FIGS. 1 and 2, the substrate processing apparatus 100 includes: a transfer housing 202 with a transfer chamber (also referred to as a “transfer region”) 203 provided therein; and a case 102 with a process chamber 201 provided therein. The wafer 200 is transferred into or out of the transfer chamber 203. The case 102 is provided on a side wall of the transfer housing 202 and serves as a process vessel which will be described later. The wafer 200 is processed in the process chamber 201. A loading port structure (also referred as an “LP”) 106 serving as a pod opening/closing structure capable of opening and closing a lid (not shown) of the pod 110 so as to transfer the wafer 200 into and out of the transfer chamber 203 is provided at a front side of the transfer housing 202 of the transfer chamber 203. That is, the loading port structure 106 is shown in a right portion of FIG. 1. For example, the loading port structure 106 includes a housing 106a, a stage 106b and an opener 106c. The stage 106b is configured to transfer the pod 110 to a position close to a substrate loading/unloading port 134 provided in front of the transfer housing 202 of the transfer chamber 203 while the pod 110 is placed on the stage 106b. The opener 106c is configured to open and close the lid provided in the pod 110. Further, the transfer housing 202 may include a purge gas circulation structure including a clean air supply structure 166 capable of circulating a purge gas such as an inert gas in the transfer chamber 203.

A gate valve 205 capable of opening and closing the process chamber 201 is provided at a rear side of the transfer housing 202 of the transfer chamber 203. That is, the gate valve 205 is shown in a left portion of FIG. 1. A transfer device 125 serving as a substrate transfer structure (also referred to as a “substrate transfer robot” or a “substrate transfer device”) capable of transferring the wafer 200 is provided in the transfer chamber 203. The transfer device 125 may include: a plurality of tweezers (also referred to as “arms”) 125a-1 and 125a-2 serving as a placement structure on which the wafer 200 is placed; a transfer structure 125b capable of rotating or linearly moving each of the plurality of tweezers 125a-1 and 125a-2 in a horizontal direction; and a transfer structure elevator 125c capable of elevating and lowering the transfer structure 125b. By consecutive operations of the plurality of tweezers 125a-1 and 125a-2, the transfer structure 125b and the transfer structure elevator 125c, it is possible to charge (load) or discharge (unload) the wafer 200 into or out of a component such as a boat 217 (which serves as a substrate retainer) described later and the pod 110. When a plurality of process chambers (including the process chamber 201) are provided as described later, a plurality of gate valves (including the gate valve 205) are provided corresponding to the number of the plurality of process chambers.

As shown in FIG. 1, in a space above the transfer chamber 203 and below the clean air supply structure 166, a wafer support 108 is provided on a wafer support table 109. The processed wafer 200 may be placed on the wafer support 108 until it is sufficiently cooled. A structure of the wafer support 108 is similar to that of the boat 217 described later. The wafer support 108 is configured to support (hold) the wafers 200 in a horizontal orientation in a vertically multistage manner by a plurality of wafer supporting grooves (wafer supporting portions). The wafer support 108 and the wafer support table 109 are provided above the substrate loading/unloading port 134 and the gate valve 205. Thus, the wafer support 108 and the wafer support table 109 deviate from a line of movement of the wafer 200 being transferred from the pod 110 to the process chamber 201 by the transfer device 125. Therefore, it is possible to cool the processed wafer 200 without reducing a throughput of a wafer processing (also referred to as a “substrate processing”). Hereinafter, the wafer support 108 and the wafer support table 109 may be collectively referred to as a “cooling area” or a “cooling region”.

According to the present embodiments, an inner pressure of the pod 110, an inner pressure of the transfer chamber 203 and an inner pressure of the process chamber 201 are controlled (adjusted) to be equal to or higher than the atmospheric pressure by about 10 Pa to 200 Pa (gauge pressure). It is preferable that the inner pressure of the transfer chamber 203 is set to be higher than the inner pressure of the process chamber 201, and the inner pressure of the process chamber 201 is set to be higher than the inner pressure of the pod 110.

### Process Furnace

A process furnace provided with a substrate processing structure as shown in FIG. 2 is disposed in a region “A” surrounded by a broken line in FIG. 1. For example, in addition to the process furnace, one or more process furnaces may be further provided.

As shown in FIG. 2, the process furnace according to the present embodiments includes the case 102 serving as a cavity (process vessel) made of a material such as a metal capable of reflecting the electromagnetic wave. A cap flange (which is a closing plate) 104 made of a metal material is in contact with the case 102 to close (seal) a ceiling surface of the case 102 via an O-ring (not shown) serving as a seal. The process chamber 201 in which the wafer 200 is processed is constituted mainly by an inner space enclosed by the case 102 and the cap flange 104. A reaction tube (not shown) made of quartz capable of transmitting the electromagnetic wave may be provided in the case 102. When the reaction tube is provided in the case 102, the process vessel (that is, the case 102) may be configured such that the process chamber 201 is constituted by an inner space of the reaction tube. Alternatively, the process furnace may not be provided with the cap flange 104. When the cap flange 104 is not provided in the process furnace, the process chamber 201 may be defined by the case 102 with a closed ceiling.

A placement table (which is a mounting table) 210 is provided in the process chamber 201. The boat 217 configured to hold (support or accommodate) the wafer 200 (or the wafers 200) is placed on an upper surface of the placement table 210. The wafer 200 (or the wafers 200) and quartz plates 101a and 101b serving as heat insulating plates are accommodated in the boat 217. The quartz plates 101a and 101b are placed with a predetermined interval therebetween to be vertically higher than and lower than the wafer 200, respectively, such that the wafer 200 (or the wafers 200) is interposed therebetween. Susceptors 103a and 103b may be provided between each of the quartz plates 101a and 101b and the wafer 200. That is, for example, one of the susceptors 103a and 103b may be provided between the quartz plate 101a and the wafer 200, and the other of the susceptors 103a and 103b may be provided between the wafer 200 and the quartz plate 101b. For example, a silicon plate (also referred to as a “Si plate”) or a silicon carbide plate (also referred to as a “SiC plate”) may be used as each of the susceptors 103a and 103b. The quartz plate 101a and the quartz plate 101b are identical to each other, and the susceptor 103a and the susceptor 103b are identical to each other. Therefore, in the present embodiments, the quartz plate 101a and the quartz plate 101b may be collectively or individually referred to as a quartz plate 101 unless they need to be distinguished separately. Similarly, the susceptor 103a and the susceptor 103b may be collectively or individually referred to as a susceptor 103 unless they need to be distinguished separately.

For example, the case 102 is a flat and sealed vessel with a circular horizontal cross-section. For example, the transfer housing 202 is made of a metal material such as aluminum (Al) and stainless steel (SUS). Further, a space surrounded by the case 102, that is, the process chamber 201 serving as a process space may also be referred to as a reaction region, and a space surrounded by the transfer housing 202, that is, the transfer chamber 203 serving as a transfer space may also be referred to as the transfer region. While the process chamber 201 and the transfer chamber 203 are adjacent to each other in the horizontal direction according to the present embodiments, the present embodiments are not limited thereto. For example, the process chamber 201 and the transfer chamber 203 may be adjacent to each other in a vertical direction.

As shown in FIGS. 1 and 2, a substrate loading/unloading port 206 is provided at a side surface of the transfer housing 202 (and the case 102) adjacent to the gate valve 205. The wafer 200 is moved (transferred) between the process chamber 201 and the transfer chamber 203 through the substrate loading/unloading port 206.

As shown in FIG. 2, an electromagnetic wave supplier (which is an electromagnetic wave supply structure) serving as a heater described later in detail is provided at a side surface of the case 102. The electromagnetic wave such as a microwave supplied through the electromagnetic wave supplier is introduced (supplied) into the process chamber 201 to heat components such as the wafer 200 and to process the wafer 200.

The placement table 210 is supported by a shaft 255 serving as a rotating shaft. The shaft 255 penetrates a bottom of the case 102 and is connected to a driver (which is a driving structure) 267 at an outside of the transfer housing 202. The driver 267 is configured to rotate the shaft 255 and the placement table 210. The wafer 200 accommodated in the boat 217 may be rotated by rotating the shaft 255 and the placement table 210 by operating the driver 267. Further, a bellows 212 covers a lower end portion of the shaft 255 to maintain an inside of the process chamber 201 and an inside of the transfer chamber 203 airtight.

According to the present embodiments, the driver 267 is configured to elevate and lower the shaft 255. By operating the driver 267 based on a height of the substrate loading/unloading port 206, the placement table 210 may be elevated or lowered until the wafer 200 reaches a wafer transfer position when the wafer 200 is transferred, and the placement table 210 may be elevated or lowered until the wafer 200 reaches a processing position in the process chamber 201 (hereinafter, also referred to as a “wafer processing position”) when the wafer 200 is processed.

An exhauster (which is an exhaust structure) configured to exhaust an inner atmosphere of the process chamber 201 is provided below the process chamber 201 on an outer circumference of the placement table 210. As shown in FIG. 2, an exhaust port 221 is provided in the exhauster. An exhaust pipe 231 is connected to the exhaust port 221. A pressure regulator (which is a pressure adjusting structure) 244 such as an APC (Automatic Pressure Controller) valve and a vacuum pump 246 are sequentially connected to the exhaust pipe 231 in series. For example, the APC valve capable of adjusting an opening degree thereof in accordance with the inner pressure of the process chamber 201 may be used as the pressure regulator 244. In the present specification, the pressure regulator 244 may also be referred to as the APC valve 244.

However, in the embodiments, the pressure regulator 244 is not limited to the APC valve described above. The pressure regulator 244 may be embodied by a combination of a conventional opening/closing valve and a pressure regulating valve so long as it is possible to receive information on the inner pressure of the process chamber 201 (for example, a feedback signal from a pressure sensor 245 which will be described later) and to adjust an exhaust amount based on the received information.

The exhauster (also referred to as an “exhaust system” or an “exhaust line”) is constituted mainly by the exhaust port 221, the exhaust pipe 231 and the pressure regulator 244. It is also possible to configure the exhaust port 221 to surround the placement table 210 such that a gas can be exhausted from the entire circumference of the wafer 200 through the exhaust port 221 surrounding the placement table 210. The exhauster may further include the vacuum pump 246.

The cap flange 104 is provided with a gas supply pipe 232 through which a process gas such as the inert gas, a source gas and a reactive gas used for performing various substrate processing is supplied into the process chamber 201.

A mass flow controller (MFC) 241 serving as a flow rate controller (flow rate control structure) and a valve 243 serving as an opening/closing valve are sequentially installed at the gas supply pipe 232 in this order from an upstream side to a downstream side of the gas supply pipe 232. For example, an inert gas source is connected to the upstream side of the gas supply pipe 232, and the inert gas is supplied into the process chamber 201 via the MFC 241 and the valve 243. When two or more kinds of gases are used for the substrate processing, it is possible to supply the gases into the process chamber 201 by connecting one or more gas supply pipes to the gas supply pipe 232 at a downstream side of the valve 243 provided at the supply pipe 232. An MFC serving as a flow rate controller and a valve serving as an opening/closing valve may be sequentially installed at each of the one or more gas supply pipes in this order from an upstream side to a downstream side of each of the one or more gas supply pipes. In addition, different gas supply pipes, each provided with an MFC and a valve may be provided for each type of the gases.

A gas supplier (which is a gas supply system or a gas supply structure) is constituted mainly by the gas supply pipe 232, the MFC 241 and the valve 243. When the inert gas is supplied through the gas supply pipe 232, the gas supplier may also be referred to as an inert gas supplier (which is an inert gas supply system or an inert gas supply structure).

### Temperature Detector

A temperature sensor (which is a temperature meter) 263 serving as a non-contact type temperature detector (temperature detecting structure) is provided at the cap flange 104. By adjusting an output of a microwave oscillator 655 described later based on temperature information detected by the temperature sensor 263, the wafer 200 is heated such that a desired temperature distribution of a temperature of the wafer 200 can be obtained. For example, the temperature sensor 263 is constituted by a radiation thermometer such as an IR (Infrared Radiation) sensor. The temperature sensor 263 is provided so as to measure a surface temperature at multiple locations on the quartz plate 101a or a surface temperature at multiple locations on the wafer 200. When the susceptor 103 described above is provided, the temperature sensor 263 may measure a surface temperature at multiple locations on the susceptor 103.

In the present specification, the term “temperature of the wafer 200” (or wafer temperature) may refer to a wafer temperature converted by temperature conversion data described later (that is, an estimated wafer temperature), may refer to a temperature obtained directly by measuring the temperature of the wafer 200 by the temperature sensor 263, or may refer to both of them.

By acquiring transition data of a temperature change of the quartz plate 101 (or the susceptor 103) and the wafer 200 in advance, the temperature conversion data indicating a correlation between a temperature of the quartz plate 101 (or the susceptor 103) and the temperature of the wafer 200 may be stored in a memory 121c or may be stored in an external memory 123, which will be described later. By preparing the temperature conversion data in advance as described above, it is possible to estimate the temperature of the wafer 200 by measuring the temperature of the quartz plate 101 (or the susceptor 103) alone and it is also possible to control the output of the microwave oscillator 655 (that is, to control the heater) based on the estimated temperature of the wafer 200.

While the radiation thermometer is exemplified as the temperature sensor 263 of measuring the temperature of the wafer 200, the present embodiments are not limited thereto. A thermocouple may be used as the temperature sensor 263 to measure the temperature of the wafer 200, or both the thermocouple and the non-contact type temperature detector (non-contact type thermometer) may be used as the temperature sensor 263 to measure the temperature of the wafer 200. However, when the thermocouple is used as the temperature sensor 263 to measure the temperature of the wafer 200, it is preferable to provide (dispose) the thermocouple in the vicinity of the wafer 200 to measure the temperature the wafer 200. That is, since it is preferable to dispose the thermocouple in the process chamber 201, the thermocouple itself may be heated by the microwave supplied from the microwave oscillator 655 described later. As a result, it is impossible to accurately measure the temperature of the wafer 200 using the thermocouple. Therefore, it is preferable to use the non-contact type thermometer as the temperature sensor 263.

While the temperature sensor 263 is provided at the cap flange 104 according to the present embodiments, the present embodiments are not limited thereto. For example, the temperature sensor 263 may be provided at the placement table 210. Further, instead of providing the temperature sensor 263 directly at the cap flange 104 or the placement table 210, for example, the temperature sensor 263 may measure the temperature of the wafer 200 indirectly by measuring the radiation reflected by a component such as a mirror and emitted through a measurement window provided in the cap flange 104 or the placement table 210. While the temperature sensor 263 alone is exemplified above, the present embodiments are not limited thereto. That is, a plurality of temperature sensors including the temperature sensor 263 may be provided according to the present embodiments.

### Electromagnetic Wave Supplier

Electromagnetic wave introduction ports 653-1 and 653-2 are provided at the side wall of the case 102. One end of a waveguide 654-1 and one end of a waveguide 654-2 through which the electromagnetic wave is supplied into the process chamber 201 are connected to the electromagnetic wave introduction ports 653-1 and 653-2, respectively. The other end of the waveguide 654-1 and the other end of the waveguide 654-2 are connected to microwave oscillators (hereinafter, also referred to as electromagnetic wave sources or electromagnetic wave oscillators) 655-1 and 655-2, respectively, serving as heating sources configured to supply the electromagnetic wave into the process chamber 201 to heat the process chamber 201. The microwave oscillator 655-1 serving as a first electromagnetic wave source and the microwave oscillator 655-2 serving a second electromagnetic wave source are configured to supply the electromagnetic wave such as the microwave to the waveguides 654-1 and 654-2, respectively. For example, as an output type of the microwave oscillators 655-1 and 655-2, a solid state type (semiconductor type) or a magnetron type may be used. For example, a magnetron type microwave oscillator is capable of performing a power control and a phase control, and a solid state type microwave oscillator is capable of performing a frequency control in addition to the power control and the phase control. For example, a step among a first modification step, a second modification step and a third modification step (which will be described later) may be performed under process conditions that are different from those of other modification steps using at least one among a first microwave (hereinafter, also referred to as an“MW1” or a “first electromagnetic wave”) described later and a second microwave (hereinafter, also referred to as an “MW2” or a “second electromagnetic wave”) described later. In such a case, it is preferable to use a microwave oscillator capable of performing the frequency control (such as the solid state type microwave oscillator) as at least one among the microwave oscillator 655-1 and the microwave oscillator 655-2. Hereinafter, in the present specification, unless they need to be distinguished separately, the electromagnetic wave introduction ports 653-1 and 653-2 may be collectively or individually referred to as an electromagnetic wave introduction port 653, the waveguides 654-1 and 654-2 may be collectively or individually referred to as a waveguide 654, and the microwave oscillators 655-1 and 655-2 may be collectively or individually referred to as the microwave oscillator 655.

Preferably, a frequency of the electromagnetic wave generated by the microwave oscillator 655 is controlled such that the frequency is within a range from 13.56 MHz to 24.125 GHz. More preferably, the frequency is controlled to a frequency of about 2.45 GHz or 5.8 GHz. In the present embodiments, the frequency of each of the microwave oscillators 655-1 and 655-2 may be the same or may be different.

While the two microwave oscillators 655-1 and 655-2 are provided on the same side surface of the case 102 according to the present embodiments, the present embodiments are not limited thereto. For example, the microwave oscillator 655 including at least one microwave oscillator may be provided according to the present embodiments. In addition, the microwave oscillator 655-1 may be provided on one side surface of the case 102 and the microwave oscillator 655-2 may be provided on another side surface of the case 102 such as a side surface facing the side surface of the case 102 at which the microwave oscillator 655-1 is provided. An electromagnetic wave supplier (which is an electromagnetic wave supply structure or an electromagnetic wave supply apparatus) serving as the heater is constituted mainly by the microwave oscillators 655-1 and 655-2, the waveguides 654-1 and 654-2 and the electromagnetic wave introduction ports 653-1 and 653-2. The electromagnetic wave supplier may also be referred to as a microwave supplier (which is a microwave supply structure or a microwave supply apparatus).

As shown in FIG. 3, a controller 121, a frequency controller 656 and a phase difference controller 657, which will be described later, are connected to each of the microwave oscillators 655-1 and 655-2. The temperature sensor 263 configured to measure the temperature of the quartz plate 101a (or the susceptor 103a) or the temperature of the wafer 200 accommodated in the process chamber 201 is connected to the controller 121. The temperature sensor 263 is configured to measure the temperature of the quartz plate 101 (or the susceptor 103) or the wafer 200 as described above and to transmit the measured temperature to the controller 121. The controller 121 is configured to be capable of controlling the heating of the wafer 200 by controlling the outputs of the microwave oscillators 655-1 and 655-2 together with the frequency controller 656 and the phase difference controller 657.

According to the present embodiments, for example, by transmitting individual control signals from the controller 121, the frequency controller 656 and the phase difference controller 657 to each of the microwave oscillators 655-1 and 655-2, it is possible to individually control the microwave oscillators 655-1 and 655-2. Further, the frequency controller 656 and the phase difference controller 657 are controlled by the controller 121.

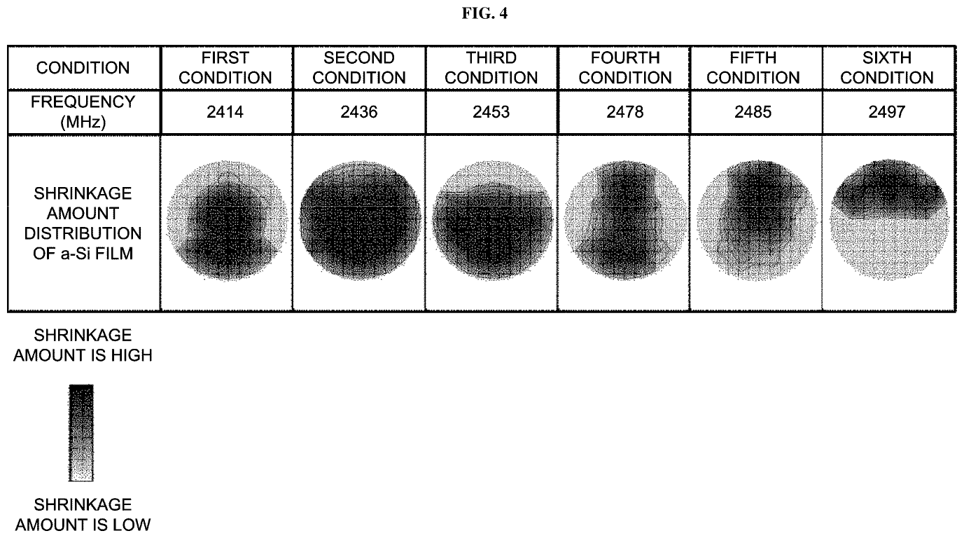

The frequency controller 656 is configured to control at least one frequency among the first microwave generated by the microwave oscillator 655-1 and the second microwave generated by the microwave oscillator 655-2. As a result, a distribution of a magnitude of an electric field and magnetic field (that is, an electromagnetic field distribution) within the process chamber 201 changes. By utilizing a change in the electromagnetic field distribution, it is possible to control a heating distribution on the wafer 200 between a region on the wafer 200 that is easily heated and other region on the wafer 200 that is hard to be heated. FIG. 4 is a diagram schematically illustrating a shrinkage amount distribution of an amorphous silicon film (hereinafter, also referred to as an “a-Si film”) processed by changing frequencies of the MW1 and the MW2 from a first condition to a sixth condition by the frequency control. In FIG. 4, a region where a shrinkage amount of the a-Si film is large represents a region that is easily heated during the a-Si film is processed. As shown in FIG. 4, when the frequencies of the MW1 and the MW2 are changed in accordance with the first condition to the sixth condition, the shrinkage amount distribution of the a-Si film, that is, the heating distribution changes.

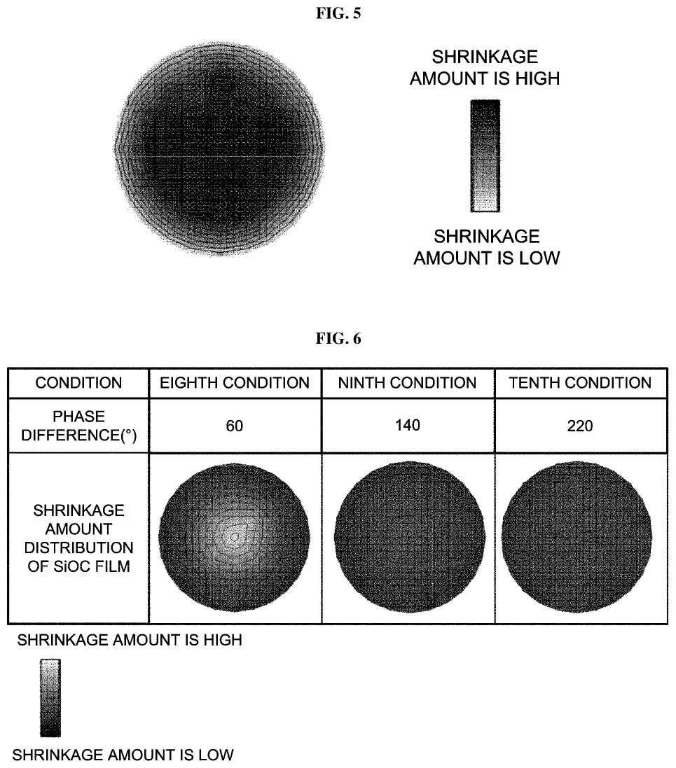

FIG. 5 is a diagram schematically illustrating the shrinkage amount distribution of the a-Si film processed under a seventh condition wherein the a-Si film is processed under the sixth condition after being processed under a third condition shown in FIG. 4. From FIG. 5, when the a-Si film is processed under the seventh condition, a region insufficiently heated by processing the a-Si film under the third condition can be intensively heated by processing the a-Si film under the sixth condition. Thus, it is possible to confirm that the shrinkage amount distribution of the a-Si film changes and becomes more uniform. As described above, by combining two modification processes in which at least one frequency among the MW1 and the MW2 is different, the region insufficiently heated in one modification process can be heated by the other modification process.

The phase difference controller 657 controls a phase difference between the MW1 and the MW2. Thereby, it is possible to change the electromagnetic field distribution within the process chamber 201. However, a change in the phase difference has a smaller effect on the electromagnetic field distribution than a change in the frequency. Therefore, it is possible to more precisely control the region within the wafer 200 that is easily heated and the region within the wafer 200 that is hard to be heated, as compared with a case where the frequency is changed.

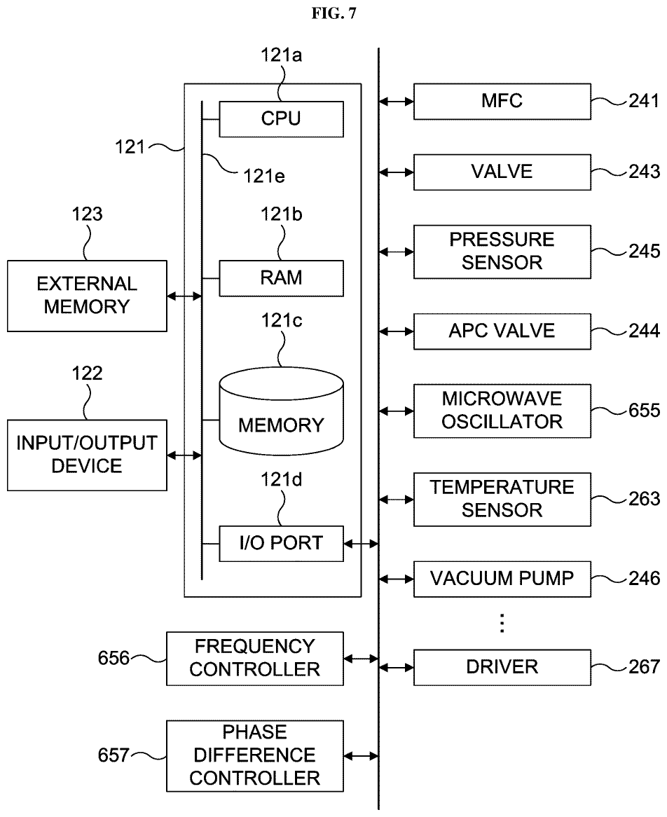

FIG. 6 is a diagram schematically illustrating a shrinkage amount distribution of a silicon oxycarbide film (also referred to as an “SiOC film”) processed by changing a phase difference between the MW1 and the MW2 from an eighth condition to a tenth condition by a phase control. In FIG. 6, a region where a shrinkage amount of the SiOC film is large represents a region that is easily heated during the SiOC film is processed. As shown in FIG. 6, when the phase difference between the MW1 and the MW2 is changed, the shrinkage amount distribution of the SiOC film, that is, the heating distribution changes. In an example shown in FIG. 6, the shrinkage amount distribution of the SiOC film under a ninth condition (phase difference of 14°) is more uniform than that of the SiOC film under the eighth condition or the tenth condition. For example, the phase difference is set to be 0° or more and less than 360∪. For example, when a phase of the MW2 is shifted by a quarter (¼) of a wavelength compared to the MW1, the phase difference between the MW1 and the MW2 is 90° (obtained as 360°×1/4=90°).

The controller 121 determines the process conditions based on temperature data obtained from the temperature sensor 263. According to the present embodiments, for example, the process conditions may include an output condition of the MW1 and the MW2, the inner pressure of the process chamber 201, a gas supply condition, a gas exhaust condition, a rotation speed of the boat 217 and the like. For example, the output condition of the MW1 and the MW2 may include a time duration of continuously supplying the MW1 and/or the MW2, an amplitude (energy) of each of the MW1 and the MW2, the phase difference between the MW1 and the MW2, the frequency of each of the MW1 and the MW2 and the like. For example, the temperature data may include a maximum temperature and an average temperature within the wafer 200, a temperature distribution within the wafer 200, a change thereof over time and the like. Even when the substrate processing is performed under the same process conditions, variations may occur in processing results for each substrate processing. By changing the process conditions (for example, the output condition of the MW1 and the MW2) based on the temperature data of the wafer 200 measured by the temperature sensor 263, it is possible to suppress the variations in the processing results.

By installing two microwave oscillators 655 (that is, the microwave oscillators 655-1 and 655-2), it is possible to independently control the frequency, the phase, and the amplitude of each of the MW1 and the MW2. Further, it is possible to change parameters (such as the phase difference, a supply timing, and an amplitude ratio between the MW1 and the MW2) in detail and easily. Thereby, it is possible to control the process conditions of the wafer 200 in detail. As a result, for example, it is possible to improve a heating uniformity, to shorten a process time, and to suppress the variations in the processing results.

### Controller

As shown in FIG. 7, the controller 121 serving as a control structure (or a control apparatus) may be constituted by a computer including a CPU (Central Processing Unit) 121a, a RAM (Random Access Memory) 121b, the memory 121c and an I/O port 121d. The RAM 121b, the memory 121c and the I/O port 121d may exchange data with the CPU 121a through an internal bus 121e. For example, an input/output device 122 constituted by a component such as a touch panel is connected to the controller 121.

For example, the memory 121c is configured by a component such as a flash memory and an HDD (Hard Disk Drive). For example, a control program configured to control operations of the substrate processing apparatus 100 and a process recipe containing information on sequences and conditions of the annealing process (modification process) of a substrate processing described later may be readably stored in the memory 121c. The process recipe is obtained by combining steps of the substrate processing described later such that the controller 121 can execute the steps to acquire a predetermined result, and functions as a program. Hereinafter, the process recipe and the control program are collectively or individually referred to as a “program.” The process recipe may also be simply referred to as a “recipe.” Thus, in the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the MFC 241, the valve 243, the pressure sensor 245, the APC valve 244, the vacuum pump 246, the temperature sensor 263, the driver 267, the microwave oscillator 655, the frequency controller 656 and the phase difference controller 657.

The CPU 121a is configured to read the control program from the memory 121c and execute the read control program. Furthermore, the CPU 121a is configured to read the recipe from the memory 121c, for example, in accordance with an operation command inputted from the input/output device 122. In accordance with the contents of the read recipe, the CPU 121a may be configured to control various operations such as: a flow rate adjusting operation for various gases by the MFC 241; an opening and closing operation of the valve 243; a pressure adjusting operation by the APC valve 244 based on the pressure sensor 245; a start and stop of the vacuum pump 246; an output adjusting operation by the microwave oscillator 655 based on the temperature sensor 263, the frequency controller 656 and the phase difference controller 657; an operation of adjusting a rotation and a rotation speed of the placement table 210 (or an operation of adjusting a rotation and the rotation speed of the boat 217) by the driver 267; and an elevating and lowering operation of the placement table 210 (or an elevating and lowering operation of the boat 217) by the driver 267.

The controller 121 may be embodied by installing the above-described program stored in the external memory 123 into the computer. For example, the external memory 123 may include a magnetic disk such as a hard disk, an optical disk such as a CD, a magneto-optical disk such as an MO and a semiconductor memory such as a USB memory and a solid state drive (SSD). The memory 121c or the external memory 123 may be embodied by a non-transitory computer readable recording medium. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

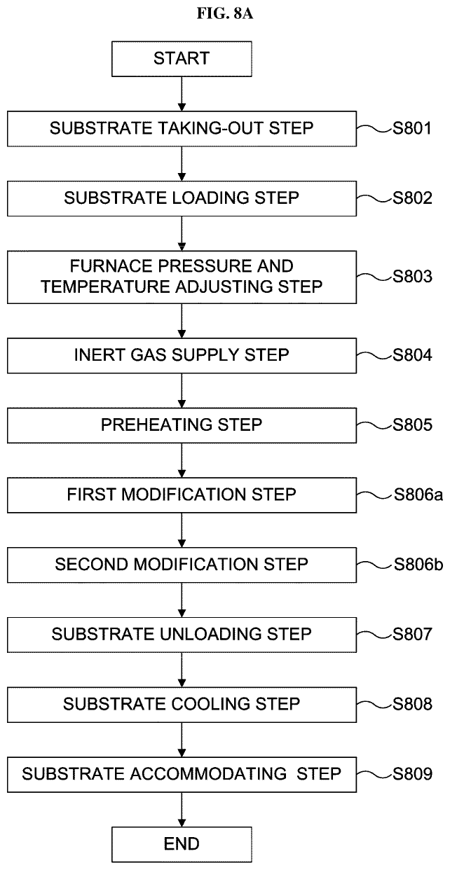

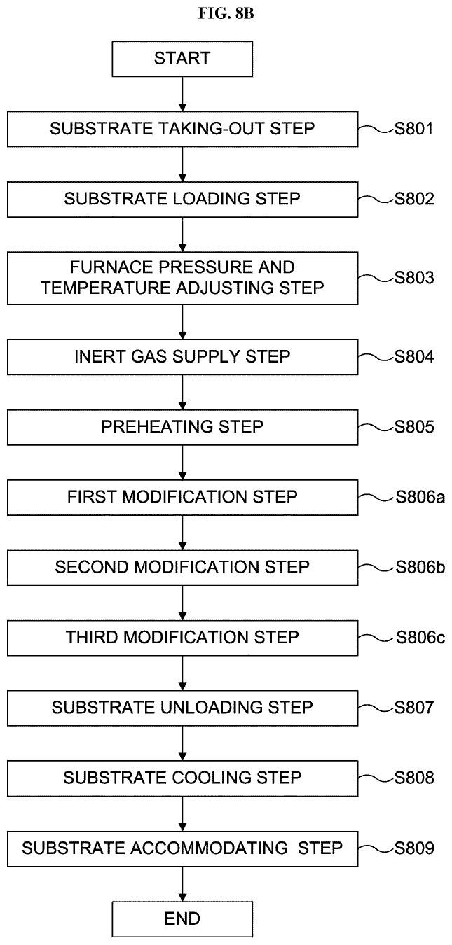

Hereinafter, an exemplary flow of the substrate processing of modifying (crystallizing) the a-Si film formed on the wafer 200 serving as the substrate, which is a part of manufacturing processes of a semiconductor device, will be described with reference to a flow chart shown in FIG. 8A. For example, the a-Si film serving as a silicon-containing film is processed according to the substrate processing. The exemplary flow of the substrate processing is performed by using the substrate processing apparatus 100 described above. In the following description, components constituting the substrate processing apparatus 100 are controlled by the controller 121 shown in FIG. 7.

In the present specification, the term “wafer” may refer to “a wafer itself” or may refer to “a wafer and a stacked structure (aggregated structure) of a predetermined layer (or layers) or a film (or films) formed on a surface of a wafer.” In the present specification, the term “a surface of a wafer” may refer to “a surface of a wafer itself” or may refer to “a surface of a predetermined layer or a film formed on a wafer.” Thus, in the present specification, “forming a predetermined layer (or film) on a wafer” may refer to “forming a predetermined layer (or film) on a surface of a wafer itself” or may refer to “forming a predetermined layer (or film) on a surface of another layer or another film formed on a wafer.” In the present specification, the terms “substrate” and “wafer” may be used as substantially the same meaning.

First, after a substrate taking-out step S801 is performed, a substrate loading step S802 is performed. In the substrate loading step S802, the wafers 200 are transferred (loaded) into the predetermined process chamber 201 (boat loading) while the gate valve 205 is opened by an opening and closing operation of the gate valve 205. That is, by using the tweezers 125a-1 used for transferring the wafer at the low temperature and the tweezers 125a-2 used for transferring the wafer at the high temperature, the wafers 200 are transferred (loaded) into the process chamber 201.

### Furnace Pressure and Temperature Adjusting Step S803

After the wafers 200 are loaded into the process chamber 201, the inner atmosphere of the process chamber 201 is controlled (adjusted) such that the inner pressure of the process chamber 201 reaches and is maintained at a predetermined pressure (for example, a pressure within a range from 10 Pa to 102,000 Pa). Specifically, the opening degree of the pressure regulator 244 is feedback-controlled based on pressure information detected by the pressure sensor 245 to adjust the inner pressure of the process chamber 201 to the predetermined pressure while vacuum-exhausting the process chamber 201 by the vacuum pump 246. In addition, in parallel with adjusting the inner pressure of the process chamber 201, the electromagnetic wave supplier is controlled to heat the process chamber 201 to a predetermined temperature. When the electromagnetic wave supplier elevates the inner temperature of the process chamber 201 to a predetermined substrate processing temperature, it is preferable that the electromagnetic wave supplier elevates the inner temperature of the process chamber 201 by a smaller output than that of the modification step (such as the first modification step, the second modification step and the third modification step) described later such that the wafer 200 is not deformed or damaged. In the present specification, a process temperature refers to the temperature of the wafer 200 or the inner temperature of the process chamber 201, and a process pressure refers to the inner pressure of the process chamber 201. In addition, a process time refers to a time duration of continuously performing a process. The same also applies to the following descriptions.

### Inert Gas Supply Step S804

After the inner pressure and the inner temperature of the process chamber 201 are controlled to predetermined values by the furnace pressure and temperature adjusting step S803, the driver 267 rotates the shaft 255 and rotates the wafers 200 via the boat 217 on the placement table 210. While the driver 267 rotates the wafers 200, the inert gas is supplied into the process chamber 201 through the gas supply pipe 232. In the present step, the inner pressure of the process chamber 201 is adjusted to a predetermined pressure within a range from 10 Pa to 102,000 Pa, for example, from 101,300 Pa to 101,650 Pa. Alternatively, the driver 267 may rotate the shaft 255 in the substrate loading step S802, that is, after the wafers 200 are loaded into the process chamber 201.

For example, a rare gas such as argon (Ar) gas, helium (He) gas, neon (Ne) gas and xenon (Xe) gas or nitrogen (N2) gas may be used as the inert gas. The same also applies to the steps described below.

### Preheating Step S805

Subsequently, when the inner pressure of the process chamber 201 reaches and is maintained at a predetermined pressure, the microwave oscillator 655-1 supplies the MW1 into the process chamber 201 under a predetermined output condition through the above-described components such as the electromagnetic wave introduction port 653-1 and the waveguide 654-1, and the microwave oscillator 655-2 supplies the MW2 into the process chamber 201 under a predetermined output condition through the above-described components such as the electromagnetic wave introduction port 653-2 and the waveguide 654-2. A preheating process (that is, the preheating step S805) of heating the wafers 200 is performed as described above. When elevating the inner temperature of the process chamber 201 to a predetermined temperature, it is preferable that the electromagnetic wave supplier elevates the inner temperature of the process chamber 201 by a smaller output than the output of the modification step described later such that the wafer 200 is not deformed or damaged.

### First Modification Step S806a

While maintaining the inner pressure of the process chamber 201 at a predetermined pressure, the microwave oscillator 655-1 and the microwave oscillator 655-2 supply the MW1 and the MW2 at least partially at the same time into the process chamber 201 through the above-described components.

### Second Modification Step S806b

While maintaining the inner pressure of the process chamber 201 at the predetermined pressure, the microwave oscillator 655-1 and the microwave oscillator 655-2 supply the MW1 and the MW2 at least partially at the same time into the process chamber 201 through the above-described components.

The second modification step is performed under process conditions (hereinafter, also referred to as a “second process conditions”) that are different from process conditions (hereinafter, also referred to as a “first process conditions”) of the first modification step in at least one among the frequency of the MW1, the frequency of the MW2 and the phase difference between the MW1 and the MW2. Thereby, it is possible to perform the second modification step such that its heating distribution on the wafer 200 is different from that of the first modification step. For example, in one modification process (that is, a processing in the second modification step, “process B”), the region insufficiently heated in the other modification process (that is, a processing in the first modification step, “process A”) can be heated. Thereby, it is possible to uniformly heat an entire of the substrate.

For example, as shown in FIG. 8B, the third modification step may be further performed after the second modification step.

### Third Modification Step S806c

While maintaining the inner pressure of the process chamber 201 at the predetermined pressure, the microwave oscillator 655-1 and the microwave oscillator 655-2 supply the MW1 and the MW2 at least partially at the same time into the process chamber 201 through the above-described components.

The third modification step is performed under process conditions (hereinafter, also referred to as a “third process conditions”) that are different from the second process conditions of the second modification step in at least one among the frequency of the MW1, the frequency of the MW2 and the phase difference between the MW1 and the MW2.

For example, at least one frequency among the MW1 and the MW2 in the second modification step may be different from that in the first modification step, and the phase difference between the MW1 and the MW2 in the third modification step may be different from that in the second modification step.

For example, the phase difference between the MW1 and the MW2 in the second modification step may be different from that in the first modification step, and at least one frequency among the MW1 and the MW2 in the third modification step may be different from that in the second modification step.

Thereby, in addition to the first modification step and the second modification step, it is possible to perform the third modification step whose heating distribution on the wafer 200 is different from those of the first modification step and the second modification step. For example, the region insufficiently heated in the first modification step and the second modification step can be mainly heated by performing the third modification step. Thereby, it is possible to more uniformly heat the entire portion of the wafer 200.

By controlling the microwave oscillators 655-1 and 655-2 in the first modification step and the second modification step (or from the first modification step to the third modification step), it is possible to heat the wafer 200 to a predetermined process temperature, and it is also possible to maintain the temperature of the wafer 200 at the process temperature for a predetermined period of time. By controlling the microwave oscillators 655-1 and 655-2 in such a manner, the a-Si film formed on the surface of the wafer 200 is modified.

The controller 121 may determine the process conditions for a subsequent processing based on the temperature data acquired from the temperature sensor 263 during the processing being executed. For example, when the time taken for the wafer 200 to reach a reference temperature in the first modification step is longer than a reference value, it is preferable to lengthen a supply time of continuously supplying the MW1 and the MW2 in at least one among the second modification step and the third modification step. Thereby, it is possible to suppress the variations in the processing results. As a result, it is possible to more uniformly heat the wafer 200.

For example, the present embodiments are described by way of an example in which the entire portion of the wafer 200 is heated. However, it is possible to obtain substantially the same effects even when the present embodiments are applied to a processing of selectively heating at least a part of a material of the wafer 200, for example, a specific material (for example, a-Si) present on the wafer 200.

In addition, it is preferable that at least one frequency among the MW1 and the MW2 supplied in at least one among the first modification step, the second modification step and the third modification step is set to a frequency at which an amount of the heat generated when irradiating the material constituting at least a part of the wafer 200 with the microwave is maximum.

### Substrate Unloading Step S807

After returning the inner pressure of the process chamber 201 to an atmospheric pressure, the gate valve 205 is opened such that the process chamber 201 communicates with the transfer chamber 203. Thereafter, a wafer 200 among the wafers 200 (which are processed (or heated) and placed on the boat 217) are transferred (unloaded) to the transfer chamber 203 by the tweezers 125a-2 (which are used for transferring the wafer at the high temperature) of the transfer device 125.

### Substrate Cooling Step S808

The wafer 200 (which is heated (processed) and transferred by the tweezers 125a-2 used for transferring the wafer at the high temperature) is moved to the wafer support 108 by consecutive operations of the transfer structure 125b and the transfer structure elevator 125c. For example, two wafers 200 are placed in the wafer support 108 by the tweezers 125a-2 used for transferring the wafer at the high temperature. By placing the wafer 200 in the wafer support 108 for a predetermined time, it is possible to cool the wafers 200.

### Substrate Accommodating Step S809

The two wafers 200 cooled by performing the substrate cooling step S808 are taken out from the wafer support 108, and then are transferred to a predetermined pod 110.

### Other Embodiments of Present Disclosure

The embodiments described above may be appropriately modified, and it is also possible to obtain substantially the same effects even when the present embodiments are appropriately modified. For example, the present embodiments are described by way of an example in which the amorphous silicon film (a-Si film) serving as the film containing silicon as a primary element (main element) is modified into a polysilicon film by performing the modification process. However, the technique of the present disclosure is not limited thereto. For example, the technique of the present disclosure may be applied to modify a film formed on the surface of the wafer 200 by supplying a gas containing at least one selected from the group consisting of oxygen (O), nitrogen (N), carbon (C) and hydrogen (H). For example, when a hafnium oxide film (HfxOy film) serving as a high dielectric film is formed on the wafer 200, a deficient oxygen in the hafnium oxide film can be supplemented and the characteristics of the high dielectric film can be improved by supplying the microwave to heat the wafer 200 while supplying a gas containing oxygen.

While the hafnium oxide film is mentioned above as an example, the technique of the present disclosure is not limited thereto. For example, the technique of the present disclosure may be applied to modify a metal-based oxide film, that is, an oxide film containing at least one metal element such as aluminum (Al), titanium (Ti), zirconium (Zr), tantalum (Ta), niobium (Nb), lanthanum (La), cerium (Ce), yttrium (Y), barium (Ba), strontium (Sr), calcium (Ca), lead (Pb), molybdenum (Mo) and tungsten (W). That is, the substrate processing described above may be preferably applied to modify a film formed on the wafer 200 such as a TiOCN film, a TiOC film, a TiON film, a TiO film, a ZrOCN film, a ZrOC film, a ZrON film, a ZrO film, a HfOCN film, a HfOC film, a HfON film, a HfO film, a TaOCN film, a TaOC film, a TaON film, a TaO film, a NbOCN film, a NbOC film, a NbON film, a NbO film, an AlOCN film, an AlOC film, an AlON film, an AlO film, a MoOCN film, a MoOC film, a MOON film, a MoO film, a WOCN film, a WOC film, a WON film and a WO film.

Without being limited to the high dielectric film, it is also possible to heat a film containing silicon as a main element and doped with impurities. A silicon-based film such as a silicon nitride film (SiN film), a silicon oxide film (SiO film), the SiOC film, a silicon oxycarbonitride film (SiOCN film) and a silicon oxynitride film (SiON film) may be used as the above-mentioned film containing silicon as the main element. For example, the impurities may include at least one metal element such as boron (B), carbon (C), nitrogen (N), aluminum (Al), phosphorus (P), gallium (Ga) and arsenic (As).

In addition, the technique of the present disclosure may be applied to modify a photoresist film based on at least one photoresist among methyl methacrylate resin (polymethyl methacrylate, PMMA), epoxy resin, novolac resin and polyvinyl phenyl resin.

While the present embodiments are described by way of an example in which the substrate processing is performed as a part of the manufacturing process of the semiconductor device, the technique of the present disclosure is not limited thereto. For example, the technique of the present disclosure may be applied to other substrate processing such as a patterning process of a manufacturing process of a liquid crystal panel, a patterning process of a manufacturing process of a solar cell and a patterning process of a manufacturing process of a power device.

Further, the technique of the present disclosure is not limited to the embodiments described above, and the technique of the present disclosure may be applied to various modified examples of the embodiments described above. For example, the embodiments described above are described in detail in order to explain the technique of the present disclosure in an easy-to-understand manner. That is, the technique of the present disclosure is not limited to those including the entire configurations of the embodiments described above.

For example, the embodiments described above are mainly described by way of an example in which the program for implementing an entirety of or a part of configurations or functions of the controller serving as the control structure is provided. However, for example, an entirety of or a part of functions of a processor serving as the controller may be implemented by a hardware by designing an integrated circuit to be used instead of the program. That is, an entirety of or a part of the functions of the processor may be implemented by using the integrated circuit such as an ASIC (Application Specific Integrated Circuit) and an FPGA (Field Programmable Gate Array) instead of the program.

For example, the embodiments described above are described by way of an example in which a single wafer type substrate processing apparatus capable of processing one or several substrates at a time is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments described above are described by way of an example in which a substrate processing apparatus including a cold wall type process furnace is used to form the film. However, the technique of the present disclosure is not limited thereto. For example, the technique of the present disclosure may be preferably applied when a substrate processing apparatus including a hot wall type process furnace is used to form the film.

According to some embodiments of the present disclosure, it is possible to improve the uniformity of heating the substrate in the heat treatment process using the electromagnetic wave.

What is claimed is:

1. A substrate processing apparatus comprising:
a process chamber in which a substrate is processed;
an electromagnetic wave source configured to output a first electromagnetic wave and a second electromagnetic wave at least partially at the same time to the process chamber; and
a frequency controller configured to be capable of controlling at least one of a frequency of the first electromagnetic wave or a frequency of the second electromagnetic wave.

2. The substrate processing apparatus of claim 1, further comprising:
a phase difference controller configured to be capable of changing a phase difference between the first electromagnetic wave and the second electromagnetic wave.

3. The substrate processing apparatus of claim 2, further comprising:
a controller configured to be capable of controlling the electromagnetic wave source and at least one of the frequency controller or the phase difference controller to perform:
(a) supplying the first electromagnetic wave and the second electromagnetic wave at least partially at the same time to the process chamber; and
(b) supplying the first electromagnetic wave and the second electromagnetic wave at least partially at the same time to the process chamber after (a) such that at least one of the phase difference, the frequency of the first electromagnetic wave, or the frequency of the second electromagnetic wave in (b) is different from that in (a).

4. The substrate processing apparatus of claim 3, wherein the controller is further configured to be capable of controlling the electromagnetic wave source and at least one of the frequency controller or the phase difference controller to perform:
(c) supplying the first electromagnetic wave and the second electromagnetic wave at least partially at the same time to the process chamber after (b) such that at least one of the phase difference, the frequency of the first electromagnetic wave, or the frequency of the second electromagnetic wave in (c) is different from that in (b).

5. The substrate processing apparatus of claim 4, wherein the controller is further configured to be capable of controlling the electromagnetic wave source, the frequency controller and the phase difference controller such that at least one of the frequency of the first electromagnetic wave or the frequency of the second electromagnetic wave in (b) is different from that in (a) and the phase difference in (c) is different from that in (b).

6. The substrate processing apparatus of claim 4, wherein the controller is further configured to be capable of controlling the electromagnetic wave source, the frequency controller and the phase difference controller such that the phase difference in (b) is different from that in (a) and at least one of the frequency of the first electromagnetic wave or the frequency of the second electromagnetic wave in (c) is different from that in (b).

7. The substrate processing apparatus of claim 1, further comprising:
a controller configured to be capable of controlling the electromagnetic wave source and the frequency controller to perform:
(a) supplying the first electromagnetic wave and the second electromagnetic wave at least partially at the same time to the process chamber; and
(b) supplying the first electromagnetic wave and the second electromagnetic wave at least partially at the same time to the process chamber after (a) such that at least one of the frequency of the first electromagnetic wave or the frequency of the second electromagnetic wave in (b) is different from that in (a).

8. The substrate processing apparatus of claim 7, wherein the controller is further configured to be capable of controlling the electromagnetic wave source and the frequency controller to perform:
(c) supplying the first electromagnetic wave and the second electromagnetic wave at least partially at the same time to the process chamber after (b) such that at least one of the frequency of the first electromagnetic wave or the frequency of the second electromagnetic wave in (c) is different from that in (b).

9. The substrate processing apparatus of claim 7, wherein at least one of the first electromagnetic wave or the second electromagnetic wave supplied in at least one of (a) or (b) is set to a frequency that maximizes an amount of a heat generated when irradiating a material constituting at least a part of the substrate with the first electromagnetic wave or the second electromagnetic wave.

10. The substrate processing apparatus of claim 7, further comprising:
a temperature meter configured to be capable of measuring a temperature at a plurality of locations on the substrate,
wherein the controller is configured to be capable of determining process conditions based on temperature data obtained from the temperature meter.

11. The substrate processing apparatus of claim 10, wherein the controller is further configured to be capable of determining the process conditions for a subsequent processing based on the temperature data acquired during a processing being executed.

12. The substrate processing apparatus of claim 10, wherein the process conditions comprise a time duration of continuously supplying the first electromagnetic wave and the second electromagnetic wave into the process chamber.

13. The substrate processing apparatus of claim 10, wherein the process conditions comprise at least one of an amplitude of the first electromagnetic wave supplied into the process chamber or an amplitude of the second electromagnetic wave supplied into the process chamber.

14. The substrate processing apparatus of claim 10, wherein the process conditions comprise at least one of the frequency of the first electromagnetic wave or the frequency of the second electromagnetic wave.

15. The substrate processing apparatus of claim 10, wherein the process conditions comprise a phase difference between the first electromagnetic wave and the second electromagnetic wave.

16. The substrate processing apparatus of claim 1, wherein the electromagnetic wave source comprises:
a first electromagnetic wave source configured to output the first electromagnetic wave; and
a second electromagnetic wave source configured to output the second electromagnetic wave.

17. The substrate processing apparatus of claim 1, wherein an output type of the electromagnetic wave source is a solid state type.

18. A substrate processing method comprising:
(A) loading a substrate into a substrate processing apparatus comprising:
a process chamber in which the substrate is processed;
an electromagnetic wave source configured to output a first electromagnetic wave and a second electromagnetic wave; and
a frequency controller configured to be capable of controlling at least one of a frequency of the first electromagnetic wave or the second electromagnetic wave; and
(B) supplying the first electromagnetic wave and the second electromagnetic wave at least partially at the same time to the process chamber.

19. A method of manufacturing a semiconductor device, comprising the substrate processing method of claim 18.

20. A non-transitory computer-readable recording medium storing a program related to a substrate processing apparatus comprising a process chamber in which a substrate is processed, an electromagnetic wave source configured to output a first electromagnetic wave and a second electromagnetic wave, and a frequency controller configured to be capable of controlling at least one of a frequency of the first electromagnetic wave or a frequency of the second electromagnetic wave, wherein the program causes the substrate processing apparatus, by a computer, to perform:
(A) loading the substrate into the substrate processing apparatus; and
(B) supplying the first electromagnetic wave and the second electromagnetic wave at least partially at the same time to the process chamber.
